(19) United States
(12) Patent Application Publication
(10) Pub. No.: US 2024/0414894 A1
(43) Pub. Date: Dec. 12, 2024

(54) THERMALLY CONDUCTIVE MOUNT

(71) Applicant: Siemens Aktiengesellschaft, 80333 München (DE)

(72) Inventors: VOLKER MÜLLER, Nürnberg (DE); STEPHAN NEUGEBAUER, Erlangen (DE); FLORIAN SCHWARZ, Fürth (DE); VLADIMIR DANOV, Erlangen (DE); STEFAN STEGMEIER, München (DE)

(73) Assignee: Siemens Aktiengesellschaft, 80333 München (DE)

(21) Appl. No.: 18/696,740

(22) PCT Filed: Sep. 16, 2022
(86) PCT No.: PCT/EP2022/075791

§ 371 Date: Mar. 28, 2024

(30) Foreign Application Priority Data
Sep. 30, 2021 (EP) 21200229.9

(51) Int. Cl. H05K 7/20

(52) U.S. Cl. CPC H05K 7/209; H05K 7/20336; H05K 7/20445; H05K 7/20936

(57) ABSTRACT

A mount includes a first metal element having a first surface for connection to a heat source, and a second metal element having a second surface for connection to a heat sink. A body made of plastic, glass or ceramic is arranged so as to abut against the first and second metal elements. The body includes through-openings which extend from a region of the first surface to a region of the second surface. The mount includes grooves in the region of the first surface and in the region of the second surface. The grooves extend over two of the through-openings. The first and second metal elements are arranged on the body such that a closed cooling channel is formed by the through-openings, the grooves and the first and second metal elements.

The invention relates to a mount, having a first surface for connection to a heat source and a second surface for connection to a heat sink. The invention also relates to a method for producing such a mount. The invention further relates to a converter with at least one mount of this kind.

Mounts, in particular mounts made of plastic, are frequently used for fastening electrical components which have different electrical potential. In this case, the mount electrically insulates these components from one another. These mounts are frequently used in converters and usually have two functions there. On the one hand, the mounts serve as a mechanical support, and on the other hand they are used for electrical insulation.

A multiplicity of plastics have good electrical insulation properties. However, mounts made of plastic have disadvantages in thermal behavior as they have only a low thermal conductivity and therefore cannot contribute to heat dissipation.

In the meantime, polymers are also known as plastics with improved thermal conductivity in the range of 10 W/mK. These are polymer systems with a high degree of filling of inorganic particles such as TIN, Al₂O₃, Si₃N₄ or graphitic or diamond-based layers. In order to achieve the aforementioned thermal conductivity, the inorganic particles are partly rod-shaped or flat in order to obtain as little contact surface as possible.

A heat-conducting insulator is known from EP 3 475 978 B1. To improve its thermal conductivity, it is proposed to equip the thermally conductive: insulator with a first part with first fins which are arranged on at least one surface of the first part, and a second part with second fins which are arranged on at least one surface of the second part. The first fins and the second fins are arranged so as to engage one another, an insulation layer being arranged between the first part and the second part, at least in the region of the fins.

Furthermore, heat pipe heat sinks have been established in the market for years for effective cooling. In this process, a liquid evaporates due to the heat input of a heat source in a closed pipe of the heat pipe heat sink. As a result of the vacuum in the closed pipe, the liquid condenses at another point on the pipe, from which the heat can then be released into the ambient air, for example. The capillary action is used to return the liquid to the pipe. The inside of the pipe is provided with a capillary structure or a porous structure for this purpose.

When operating a pulsating heat pipe, also referred to as an oscillating heat pipe, the capillary structure is not required. The inside of the pipe can also be smooth. In the pulsating heat pipe, the heat transfer also takes place via a liquid, parts of the liquid being present in gaseous form in the pipe. Due to the heat input, the liquid in the pipe begins to move back and forth. This pulsation gives the heat pipe its name.

The object of the invention is to improve the thermal conductivity of an electrically insulating mount.

This object is achieved by a mount, having a first surface for connection to a heat source and a second surface for connection to a heat sink, the first surface and/or the second surface being formed by a metal element, the mount also having a body made of plastic, glass or ceramic, the body being arranged so as to abut against the metal element of the first surface and against the metal element of the second surface, the body having a through-opening or through-openings which extend from the region of the first surface to the region of the second surface, the mount having grooves in the region of the first surface and in the region of the second surface if there is more than one through-opening, which grooves extend over two of the through-openings, the metal elements being arranged on the body such that a closed cooling channel is formed by the through-openings, the grooves and the metal elements. This object is also achieved by a method for producing such a mount, the body being formed by means of an injection molding method or milling method, the body then being metallized in the region of the first surface and in the region of the second surface, the metal elements each being fastened by means of a soldering method, a welding method or an adhesive method to the metallized region of the body. The invention is further achieved by a converter with at least one such mount, a capacitor and/or a power rail being fastened to a heat sink by means of the mount in the converter.

Further advantageous embodiments of the invention are specified in the dependent claims.

The invention is based, among other things, on the fact that thermal conductivity with simultaneous electrical insulation capability can be achieved by integrating cooling according to the heat pipe principle into a mount with a body made of plastic. For this purpose, the principle of a customary heat pipe can be used, which uses the effect of evaporation and reflux via a porous structure. Alternatively it is possible to use the principle of two-phase cooling as in a pulsating heat pipe in the plastic body. The mount has a body comprising plastic or glass. The body may be made entirely of plastic or glass. Alternatively, it is possible to design only parts of the body of plastic or glass. Advantageously, such an insulating layer of plastic or glass is formed along the first and/or second surface as well as along the through-openings. At the points of heat transfer, that is to say, at the contact points with the heat source and with the heat sink, the mount has a metal element which improves the heat transfer. The electrically insulating property is achieved by the body made of plastic. In this case, the first surface or the second surface may be designed as a metal element. Alternatively, it is possible to design both surfaces, i.e. the first surface and the second surface, respectively as a metal element. The metal element may be a body that is inherently dimensionally stable. Alternatively, it is possible to apply the metal element to the body as a thin layer. It has been found that a pulsating heat pipe can also be realized within a body made of plastic. In addition, a barrier layer can be arranged in the body. This reliably prevents a problem with oxygen diffusion during operation of the pulsating heat pipe. This barrier layer can be formed using an inorganic material or special plastic films. In this case, it is then also possible for the body to be made of glass or metal as an alternative to plastic. If there are no requirements for electrical insulation strength, it is also possible to design the body as a metal.

At least one through-opening is arranged in the body. This can be filled with a porous material such as, for example, metal foam. As a result of the capillary action, conventional heat pipe behavior can thus be achieved. This improves heat transport within the mount.

Alternatively, it is possible to use the behavior of a pulsating heat pipe for heat transfer. To this end, it is advantageous if the body has a plurality of through-openings extending from the region of the first surface to the region of the second surface. Two of the through-openings are connected by a groove on the surface of the body, in particular at the end of the individual through-openings, in such a way that a closed channel is formed in the interior of the mount with the attached metal elements and forms a closed cooling channel. This closed cooling channel is also referred to as a closed circuit. The through-openings do not necessarily have to run in a straight line in the body. In addition to a rectilinear connection, sawtooth-like connections, spiral connections or even complex different connections have also proven to be advantageous for the formation of a closed channel.

The metal elements are fastened to the body. This can be achieved, in particular, in a cost-effective and simple manner by producing the body by means of an injection molding method. Subsequently, the body is metallized in the region of the first surface and in the region of the second surface. As a result, the metal elements can be permanently and reliably fastened to the body in this region in a simple and cost-effective manner by means of a soldering method or a welding method. This method is not only cost-effective but is also suitable for mass production. In addition, a permanently reliable connection can be established between the metal element and the body, which gives the mount a long service life. As an alternative to soldering or welding, the metal element can also be glued to the body.

The mount can be used, for example, in a converter. There are numerous electrical components in a converter. Some of these components heat up to such an extent that measures to dissipate heat are required. For this purpose, for example, semiconductors are mounted on heat sinks. In addition, there is also often the need to dissipate heat from power rails and capacitors so that these components do not limit or reduce the conductivity of the converter in terms of their design. By using the proposed mount, these components such as, for example, power rails and capacitors, can not only be securely fastened in the converter and isolated from existing other electrical potentials, but the mounts can also contribute to heat dissipation, i.e. cooling or extraction of heat, in these components. For this purpose, the component in question, such as for example a capacitor or power rail, is fastened to a heat sink by means of the proposed mount. The mount brings about a mechanically fixed arrangement of the component in the converter, sufficient electrical insulation from existing electrical potentials and good heat dissipation of the component. It is particularly advantageous to arrange a power rail in the vicinity of a converter, i.e. at a distance of up to 25 cm from the converter, and to fasten the power rail therewith. High temperatures often occur in the region of converters. On the one hand, as the converter prevents natural convection when it surrounds the power rail, . . . and on the other hand as the converter itself still contributes to heating. Examples of converters are current converters and voltage converters.

In addition, in some circumstances, the cross-section of the power rail can be selected to be smaller due to the heat dissipation of the power rail by means of the proposed mount. As a result, smaller converters can be used and the installation situation in a cabinet of the converter is relaxed. If necessary, the converter can also be produced in a smaller size. In addition, this heat dissipation increases the service life or the performance of the converter and the components arranged therein.

The mount has, for example, an injection-molded sleeve as a body, which is bonded or welded to a base cover. The base cover is preferably formed by the metal element for reasons of thermal conductivity. A channel which is suitable for the operation of a pulsating heat pipe or a customary heat pipe is formed by bores, the insertion, press-fitting or gluing of inner parts or in any other way. Complete tightness between the channels is not absolutely necessary. The necessary grooves for forming the closed channel can be introduced in inner parts and/or in the body and/or in the metal elements, that is to say, the base covers.

The advantage compared with other solutions is that production can be carried out without very slim cores in the tool, and the channels for the operation of the pulsating heat pipe can be flexibly inserted at the base of the mount. Furthermore, an embodiment with a completely closed plastic sleeve of the body is possible if there are high insulation requirements or if cost savings are sought. It is then possible to use more advantageous plastic in the inner region with poorer properties. Due to the poor thermal conductivity of the plastics, it is then advantageous if the channels are formed over a large area in the region of the first and second surface. If metal bushes are to be used for fastening, they can likewise contribute to heat dissipation. Thermal contact therefore takes place not only on the surface of the mount but can also take place via the fastening means in the core. The metal bush can be arranged in a cavity of the body and transfers the heat to the core area of the mount by way of heat conduction. The bushes can be fastened in such a way that they are almost exclusively subjected to shear stresses in the application, which are much more tolerable or bearable than tensile or peeling loads.

In this case, construction with a smaller number of parts is possible. As a result, however, the floor area, that is to say the surface which forms the metal element, cannot be fully used for heat dissipation or the individual parts are more expensive to produce. At least two individual parts are required.

The remaining internal volume in the mount can be used for other purposes. With a solid core, the heat dissipation or heat conduction in the material is supported and heat buffering is achieved. In addition, when filling with phase change materials, even greater heat buffering is possible. If additional fluid is introduced as a reserve, the service life of the component can be significantly extended in the event of minimal diffusion losses or contamination.

Due to the particularly effective heat transfer, even particularly long mounts with high thermal conductivity can be produced. Lengths of more than 25 cm or even more than 50 cm can be produced with high thermal conductivity of more than 100 W/mK.

In an advantageous embodiment of the invention, the grooves are arranged in the metal element. In this way, the through-openings of the body can be adapted to the application with the aid of the metal cover, according to requirements.

In a further advantageous embodiment of the invention, there is a liquid in the cooling channel, parts of the liquid being present in gaseous form in the cooling channel, the liquid being a dielectric fluid. It has proven to be advantageous if a . . . vacuum is arranged in the closed cooling channel. This can be achieved by evacuation. It is then ensured that the liquid is present in sufficient quantities both in its liquid form and in the gaseous form. If particularly high demands are placed on the electrical insulation strength, it has proven to be advantageous to arrange dielectric fluids in the closed cooling channel. These do not reduce the insulation strength between the two metal elements, or only insignificantly, and thus ensure a particularly high electrical insulation capacity of the mount.

In a further advantageous embodiment of the invention, the mount and the body are cylindrical in shape, the first surface and the second surface each being formed by one of the base areas of the cylinder, the metal elements being annular in shape. Thanks to the cylindrical embodiment, the metal elements can be permanently fastened to the body in a particularly simple manner by means of a laser method. Due to the cylindrical shape, a clean fusion between the plastic and metal element can take place. Depending on the selection of the wavelength used for the welding process and the plastics, the heat can be applied precisely at the interface. As an alternative to the embodiment as a cover, it may be advantageous to use a thermally conductive polymer instead of the metal element. In this way, the body and the polymer can be permanently bonded to one another in a simple manner by means of bonding.

In the embodiment of the cylindrical shape, the first and the second surface can have any angle with respect to one another. This means that the first and second surface need not necessarily be arranged in parallel. Compared to a section through the cylinder perpendicular to the height, the first and/or second surface can have any desired angle.

The cylindrical shape does not have to have a circular cross-section either. As an alternative to the circular cross-section, cross-sections in an oval shape or as a polygon, in particular as hexagonal cross-sections, can also be designed advantageously and cost-effectively with high mechanical stability.

In a further advantageous embodiment of the invention, a glass-fiber-reinforced plastic film is arranged around the lateral surface of the cylindrical body. This plastic film increases the compressive strength of the mount to the outside. In this way, polymers can then be used for the plastic of the body, which have a high chemical resistance to the liquid in the closed channel, have a high thermal stability, are very cost-effective and do not have high pressure stability. Pressure stability is then achieved by means of the glass-fiber-reinforced plastic film. This makes the mount particularly cost-effective to produce and means that it can also maintain good thermal conductivity over the entire service life.

In a further advantageous embodiment of the invention, a metal foam is arranged in the cooling channel. This metal foam serves as a porous material to achieve the cooling function, that is to say the transfer of heat, within the body with further two-phase cooling. This can take place instead of cooling according to the principle of the pulsating heat pipe or in combination therewith. To this end, a porous structure is arranged in the closed channel. As a result of the porous structure, the liquid is guided to the heat source regardless of the installation position of the heat sink. In this case, the porous structure can be arranged laterally at the edge of the channel. The steam can then flow through the free part of the channel. Alternatively, the porous structure may completely fill, to ensure the effect of transporting the liquid at a high throughput. Especially when transporting the liquid against gravity, it may be advantageous to completely fill the channel with porous material. This porous structure can be formed by a metal foam or by a plastic, in particular by an additively manufactured plastic. If an electrical insulation capability of the mount is also required, it has proven advantageous when using metal foam to provide an electrically insulating element, such as for example a plastic element, as an alternative to the metal element.

In a further advantageous embodiment of the invention, the cross-section of the through-openings decreases starting from the region of the second surface in the direction of the region of the first surface. Due to the tapering, that is to say the reduction of the cross-section, in the direction of the heat source, it is ensured that the liquid always accumulates on the warm side and, as a result, the heat transfer not only has a high performance but can also start more easily. In particular, this is advantageous if gravity counteracts the accumulation of liquid in the region of the heat source. Thus, through tapering, a mount can be realized which can be used regardless of position.

In a further advantageous embodiment of the invention, means for fastening the mount are arranged on or in the metal element. The metal element has such a high strength that the arrangement of fastening means is particularly advantageous there. By introducing a thread into the metal element, it is also possible to realize high torques for the fastening. In this case, threaded bushings and/or threaded bolts can also be arranged at least partially on or in the metal element. The mount can be arranged at any desired location of the mount. For example, the mount can be arranged on the metal element or on the body or on both of these components.

In a further advantageous embodiment of the invention, a threaded bushing is arranged in the body or a threaded bolt is arranged on the body. A threaded bushing or a threaded bolt for fastening may be embedded in the body. This or the latter can then be used for screwing to a component such as, for example, a capacitor. As high torques are often not permissible for the screw connection, the arrangement of the connecting means in the plastic of the body, in particular in a cavity of the body, can also be provided. This connecting means and the arrangement in the body can also be produced cost-effectively. If, for example, the screw drive is also accessible on the side and thus the torque is transmitted directly to the bolt, it can also be screwed with larger torques.

In a further advantageous embodiment of the invention, the cooling channel has a cross-section in the range of 0.25 mm² to 10 mm². On this scale, the capillary action of the heat pipe is sufficiently effective against gravity, so that a sufficiently good heat transfer through the heat pipe can be ensured, regardless of whether or not the pulsating effect is exploited.

In a further advantageous embodiment of the invention, the metal element has a metal rib which engages in the body. This metal rib may be a kind of pipe attachment which is arranged in a circular manner on the metal element. This pipe attachment can either protrude into the channel or form part of the closed channel. A particularly good heat transfer between the respective surfaces and the liquid of the heat pipe cooling can be achieved due to the metal rib. The advantage can be further improved if the metal rib has an additional structure such as spikes, a metal foam or metal mesh. This increases the surface relevant for heat transfer and leads to improved heat transfer through the mount.

In a further advantageous embodiment of the invention, the metal element has a further metal rib which engages in the cooling channel in such a way that an interface between the cooling channel and the metal element is enlarged. This type of further metal rib also increases the surface relevant for heat transfer and leads to improved heat transfer through the mount.

In a further advantageous embodiment of the invention, the through-openings have an enlargement of the cross-section in sections, so that a reservoir is formed. As a result, storage reservoirs for the liquid can be created in a simple manner. Thus, a possible loss of liquid can be counteracted.

The invention is described and explained in more detail hereinafter with reference to the exemplary embodiments shown in the figures. The figures show:

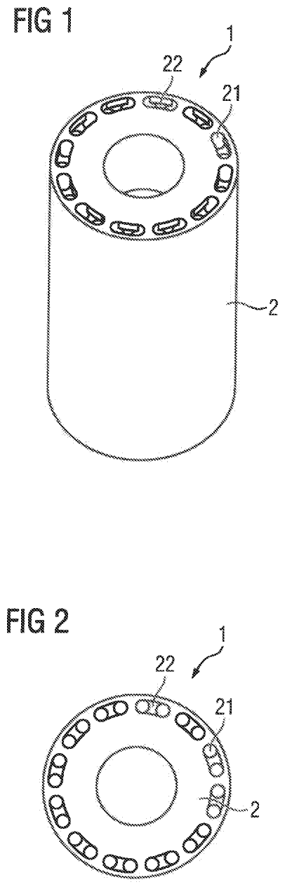

FIGS. 1 to 9 Different views and embodiments of a mount,

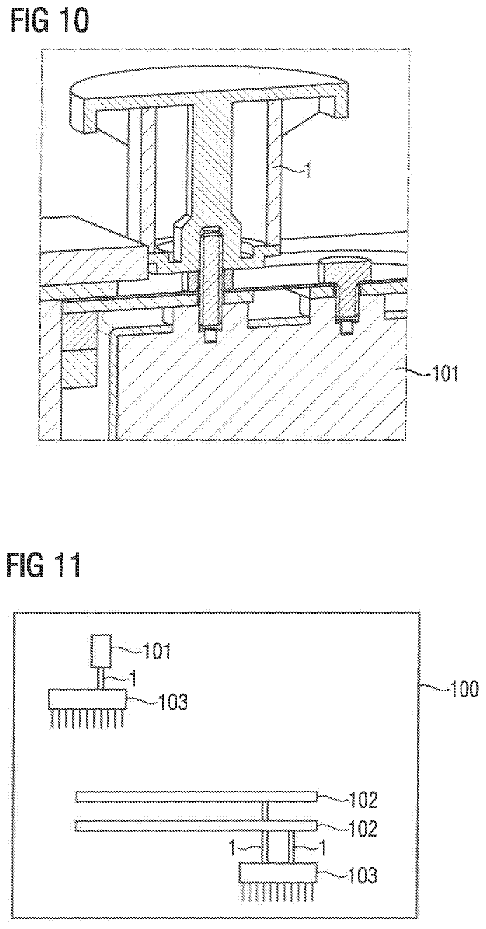

FIG. 10 An example of the application of the mount, and

FIG. 11A diagrammatic view of a converter.

FIG. 1 shows parts of a mount 1. The mount has a body 2 preferably made of a plastic. This plastic has an electrically insulating effect, but poor thermal conductivity. In order to improve the thermal conductivity, through-openings 21 are arranged in the body 2. In the region of the base areas of the cylindrical body 2, grooves 22 are arranged in the through-openings in such a way that a closed cooling channel 23 is formed from the through-openings 21 and the grooves 22. The lateral surface of the cylindrical body 2 can also be surrounded by a glass-fiber-reinforced plastic film to increase the compressive strength.

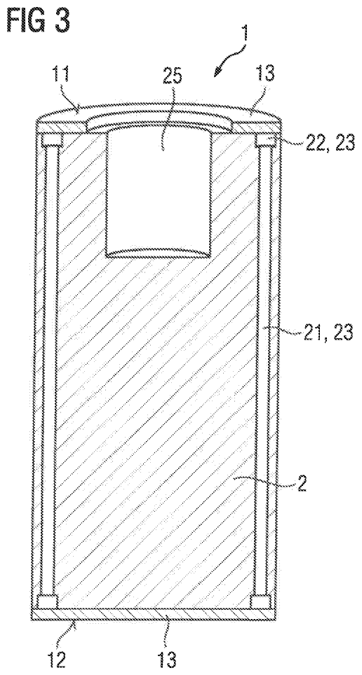

The through-openings 21 and grooves 22 are shown in more detail in FIG. 2, the view being directly of the base area of the cylindrical body 2 in this diagram. FIG. 3 shows a section through the mount 1. In order to avoid repetition, reference is made to the description of FIGS. 1 and 2, as well as to the reference characters introduced therein. A metal element 13 is arranged on each of the two base areas of the cylindrical body 2. The metal elements 13 form a first surface 11 for connection to a heat source and a second surface 12 for connection to a heat sink. In the sectional view, the through-opening 21 is clearly visible. In the region of the base area, the groove 22 can also be seen, which results in a closed cooling channel 23 consisting of the through-opening 21 and the groove 22. A mixture of liquid and gaseous components of a liquid is arranged in this closed cooling channel 23. In addition, the cooling channel is evacuated so there is a vacuum there. As a result of this embodiment, heat pipe cooling, in particular pulsating heat pipe cooling, can be realized through the closed cooling channel. The metal element 13 is designed as a ring. This permits a threaded bushing to be arranged in a cavity 25 of the body 2 to which an electrical component can be fastened. This cavity 25 can be arranged on both base areas of the body 2.

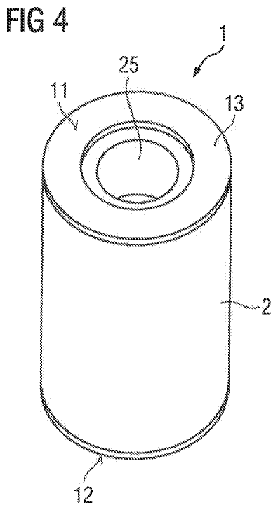

FIG. 4 shows from a different perspective how the metal element 13, embodied as a ring, is arranged on the body 2. To avoid repetition, reference is made to the description of FIGS. 1 to 3, as well as to the reference characters introduced therein.

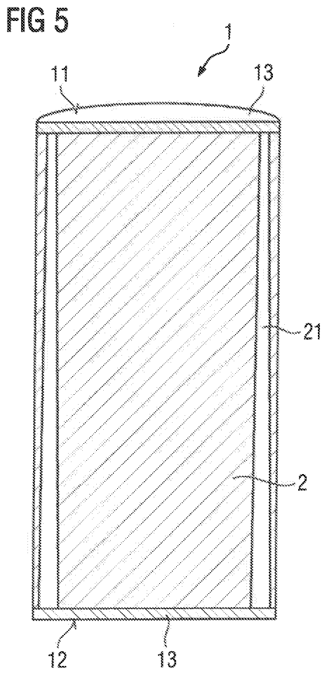

FIG. 5 shows a section through a further exemplary embodiment of the mount 1. To avoid repetition, reference is made to the description of FIGS. 1 to 4, as well as to the reference characters introduced therein. In this case, the first surface 11 is provided for connection to a heat source and the second surface 12 for the connection to a heat sink. In order to design the cooling in a positionally independent manner, the through-opening 21 tapers from the second surface 12 in the direction of the first surface 11. In addition, a cross-section of the closed cooling channel 23 in the range of 0.25 mm² to 10 mm² has proven to be advantageous for positionally independent use.

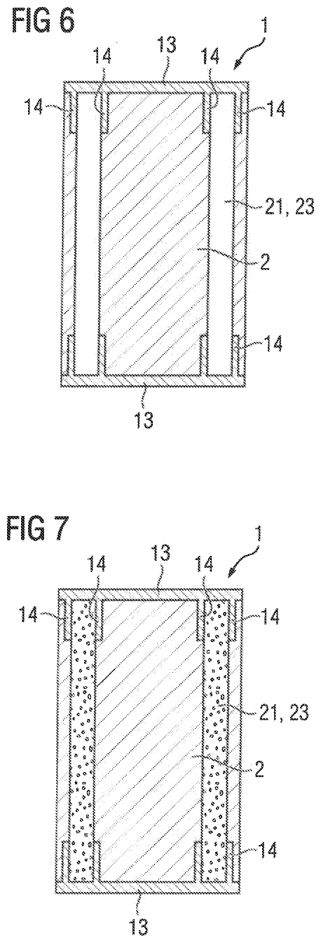

FIG. 6 shows a further exemplary embodiment of a mount 1. To avoid repetition, reference is made to the description of FIGS. 1 to 5, as well as to the reference characters introduced therein. At least one metal rib 14 is arranged on each of the metal elements 13. This is preferably round or circular and engages in the body 2 in such a way that the metal rib 14 extends along the cooling channel 23, which results from the through-opening 21 and the groove 21. This results in a particularly good heat transfer from the heat source to the heat pipe cooling and from the heat pipe cooling to the heat sink.

FIG. 7 shows a further exemplary embodiment of a mount 1. To avoid repetition, reference is made to the description of FIGS. 1 to 6, as well as to the reference characters introduced therein. In this case, the through-openings 21 are . . . partially or completely filled with a porous material. In this case, in particular a metal foam can be arranged in the through-openings 21 as a porous material. The mount 1 is therefore suitable not only for the transfer of heat according to the principle of a pulsating or oscillating heat pipe, but also according to the principle of a conventional heat pipe. These two principles can also be used in combination for heat transport in the mount 1.

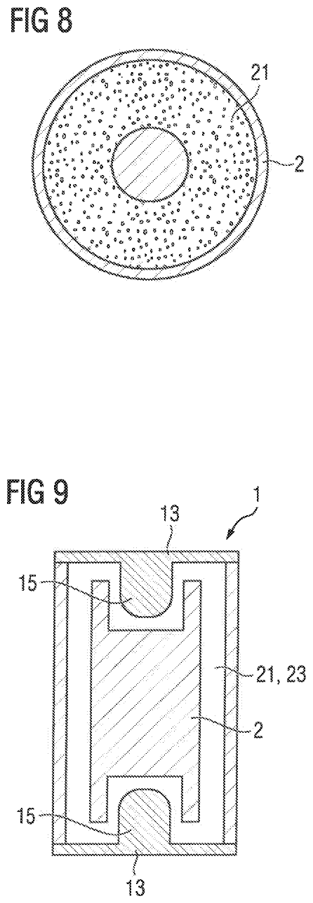

For operation as a conventional heat pipe, there is also no need for an extended cooling channel. Rather, it is sufficient to arrange only one through-opening 21, as shown in FIG. 8, in the body 2 and to fill it, at least partially, with a porous material such as, for example, a metal foam.

FIG. 9 shows a further exemplary embodiment of a mount 1. To avoid repetition, reference is made to the description of FIGS. 1 to 8, as well as to the reference characters introduced therein. The metal element 13 has a further metal rib 15, which further increases the interface between the metal element 13 and the cooling channel 23. As a result, the heat transfer between the metal elements 13 and the heat pipe cooling is further improved. In addition, it is possible to design the further metal rib 15 in the metal element 13 as a connecting element. For example, a threaded hole or a bolt may be arranged in the further metal rib 15, with which the mount 1 can be mechanically connected to a component.

FIG. 10 shows such a connection between a capacitor 101 as a heat source and the mount 1. A thread or a threaded bushing is arranged in the cavity 25 by means of which the mount 1 and the capacitor 101 are mechanically connected.

FIG. 11 shows a diagrammatic view of a converter 100, which has, among other things, a capacitor 101, power rails 102 and heat sinks 103. The capacitor 101 is connected to a heat sink 103 by means of the mounts 1. This heat sink 103 may primarily be used for cooling other components, such as for example, . . . for cooling semiconductors. The capacitor 101 is fastened in the converter 100 by means of the mount 1. In addition, heat is transferred to the heat sink 103 via the mount 1. In other words, the capacitor 101 is heated or cooled by the heat sink 103 via the mount 1.

The same applies to the power rails 102. The power rails 102 are securely arranged, i.e. fastened, in the converter 100 by means of the mounts 1. In addition, the mount 1 transfers heat from the power rails 102 to the heat sinks 103. The arrangement of the mount 1 in the region of a converter is particularly advantageous. As the converter can impede natural convection, an increased temperature is to be expected in the region of the converter. This increase in temperature by the converter can be reliably counteracted with the mount 1 if the latter is arranged in the region of the converter.

In summary, the invention relates to a mount, having a first surface for connection to a heat source and a second surface for connection to a heat sink. To improve thermal conductivity in an electrically insulating mount, the first surface and/or the second surface respectively are/is formed by a metal element, wherein the mount also has a body made of plastic, glass or ceramic, wherein the body is arranged so as to abut against the metal element of the first surface and against the metal element of the second surface, wherein the body has a through-opening or through-openings which extend from the region of the first surface to the region of the second surface, wherein the mount has grooves in the region of the first surface and in the region of the second surface if there is more than one through-opening, which grooves extend over two of the through-openings, wherein the metal elements are arranged on the body such that a closed cooling channel is formed by the through-openings, the grooves and the metal elements. Furthermore, the invention relates to a method for producing such a mount. The invention also relates to a converter with at least one such mount.

What is claimed is:

1.-15. (canceled)

16. A mount, comprising:
a first metal element including a first surface for connection to a heat source;
a second metal element including a second surface for connection to a heat sink;
a body made of plastic, glass or ceramic and arranged so as to abut against the first and second metal elements, said body comprising through-openings which extend from a region of the first surface to a region of the second surface,
wherein the mount comprises grooves in the region of the first surface and in the region of the second surface, said grooves extending over two of the through-openings, and
wherein the first and second metal elements are arranged on the body such that a closed cooling channel is formed by the through-openings, the grooves and the first and second metal elements.

17. The mount of claim 16, wherein the grooves are arranged in the first and second metal elements.

18. The mount of claim 16, further comprising a liquid received in the cooling channel and being a dielectric fluid, wherein parts of the liquid are present in gaseous form in the cooling channel.

19. The mount of claim 16, wherein the mount and the body are designed in a form of a cylinder, wherein the first surface and the second surface are each formed by a base area of the cylinder, wherein the first and second metal elements are annular.

20. The mount of claim 19, further comprising a glass-fiber-reinforced plastic film arranged around a lateral surface of the cylindrical body.

21. The mount of claim 16, further comprising a metal foam arranged in the cooling channel.

22. The mount of claim 16, wherein the through-openings have a cross-section which decreases in a direction of the region of the first surface starting from the region of the second surface.

23. The mount of claim 16, further comprising fasteners arranged on or in the first and second metal elements to fasten the mount.

24. The mount of claim 16, further comprising a threaded bushing arranged in the body or a threaded bolt arranged on the body.

25. The mount of claim 16, wherein the cooling channel has a cross-section in a range of 0.25 mm² to 10 mm².

26. The mount of claim 16, wherein the first and second metal elements each comprise a metal rib which engages in the body.

27. The mount of claim 16, wherein the first and second metal elements each comprise a metal rib which engages in the cooling channel in such a way that an interface between the cooling channel and a corresponding one of the first and second metal elements is enlarged.

28. The mount of claim 16, wherein the through-openings have at least one enlarged section in cross-section so as to form a reservoir.

29. A method for producing a mount as set forth in claim 16, the method comprising:
forming the body by injection molding or milling;
metallizing the body in the region of the first surface of the first metal element and in the region of the second surface of the second metal element; and
fastening each of the first and second metal elements to a metallized region of the body by soldering, welding method or adhesive.

30. The method of claim 29, further comprising arranging the grooves in the first and second metal elements.

31. The method of claim 29, further comprising filling a liquid in a form of a dielectric fluid in the cooling channel, with parts of the liquid being present in gaseous form in the cooling channel.

32. The method of claim 29, further comprising:
designing the body in a form of a cylinder; and
arranging a glass-fiber-reinforced plastic film around a lateral surface of the cylindrical body.

33. The method of claim 29, further comprising arranging a metal foam in the cooling channel.

34. The method of claim 29, further comprising enlarging at least one section of the through-openings so as to form a reservoir.

35. A converter, comprising:
a mount comprising a first metal element including a first surface for connection to a heat source, a second metal element including a second surface for connection to a heat sink, a body made of plastic, glass or ceramic and arranged so as to abut against the first and second metal elements, said body comprising through-openings which extend from a region of the first surface to a region of the second surface, wherein the mount comprises grooves in the region of the first surface and in the region of the second surface, said grooves extending over two of the through-openings, and wherein the first and second metal elements are arranged on the body such that a closed cooling channel is formed by the through-openings, the grooves and the first and second metal elements;
a heat sink; and
at least one of a capacitor and a power rail fastened to the heat sink by the mount.
